(19) United States
(12) Patent Application Publication
(10) Pub. No.: US 2019/0385908 A1
(43) Pub. Date: Dec. 19, 2019

(54) Treatment And Doping Of Barrier Layers

(71) Applicant: Applied Materials, Inc., Santa Clara, CA (US)

(72) Inventors: Xiangjin Xie, Fremont, CA (US); Rui Li, San Jose, CA (US); Goichi Yoshidome, Albany, CA (US); Adolph M. Allen, Oakland, CA (US); Xianmin Tang, San Jose, CA (US)

(21) Appl. No.: 16/442,941

(22) Filed: Jun. 17, 2019

Related U.S. Application Data
(60) Provisional application No. 62/686,084, filed on Jun. 17, 2018.

(51) Int. Cl. H01L 21/768; H01L 21/311; H01L 21/3115; H01L 21/3205

(52) U.S. Cl. CPC H01L 21/76846; H01L 21/32051; H01L 21/3115; H01L 21/31122

(57) ABSTRACT

Methods of treating a film on a substrate in a PVD chamber are described. The methods include biasing the substrate with an RF power to provide a biased substrate, etching the film on the biased substrate with at least one gas, and sputtering first and second sources of cobalt onto the film on the biased substrate to form a doped film. Some embodiments advantageously provide doped films as liners or barrier layers. Some embodiments provide for the deposition of bulk materials on the doped films. Some embodiments advantageously minimize the thickness of the individual layers.

### CROSS-REFERENCE TO RELATED APPLICATIONS

This application claims priority to U.S. Provisional Application No. 62/686,084, filed Jun. 17, 2018, the entire disclosure of which is hereby incorporated by reference herein.

### FIELD

Embodiments of the disclosure generally relate to methods of treating and/or doping barrier layers. More particularly, some embodiments of the disclosure are directed to methods of treating and doping ALD tantalum nitride films with cobalt.

### BACKGROUND

A substrate is used to build structures or devices for the semiconductor industry. The devices are constructed using thin film deposition to deposit layers of materials to form conductors, vias, semiconductors, and other structures/devices in the substrate. As the sizes of these devices shrink due to the demand for smaller and faster electronics, greater control over the thin film deposition processes is required to ensure proper device functionality. The smaller size of devices has led to a shift from using physical vapor deposition (PVD) chambers to atomic layer deposition (ALD) chambers. The ALD chambers allow surface control methods to produce highly uniform films over the entire device structure. However, when ALD chambers are used to produce barrier films, the barrier films have a high resistivity and low density, providing a poor quality barrier film. PVD chambers produce films with good barrier properties like higher density and lower resistivity, but the films are non-conformal, often resulting in improperly constructed devices on the substrate.

Specifically, for 5 nm node and below, barrier and liner thickness for copper interconnects becomes even more challenging with respect to resistivity reduction and device reliability. Also, the baseline thickness of a barrier film and liner at 5 nm is ˜45 Å. Higher thicknesses provide less space for copper gapfill and increase resistivity.

Therefore, there is a need for the reduction of barrier and liner layer thicknesses to make room for copper as well as improving barrier properties and resistivity.

### SUMMARY

One or more embodiments of this disclosure are directed to a method of doping a film. The method comprises providing a substrate with a film deposited thereon. The substrate is biased with an RF power at a first RF power frequency to provide a biased substrate. The film is etched on the biased substrate with at least one gas. First and second sources of cobalt are sputtered onto the film on the biased substrate to form a doped film. The first source of cobalt is supplied with RF power or DC power, and the second source of cobalt is supplied with RF power at a second RF power frequency and with DC power.

Additional embodiments of this disclosure are directed to a method of forming a doped film. The method comprises depositing a film on a substrate in a process chamber. The substrate is transferred to a physical vapor deposition process chamber. The film is biased with an RF power at a second RF power frequency. The film is etched with at least one gas. The film is simultaneously doped by sputtering a first and a second source of cobalt onto the film to form a doped film. The first source of cobalt is supplied with RF power or DC power, and the second source of cobalt is supplied with RF power at a first RF power frequency and with DC power.

Further embodiments of this disclosure are directed to a method of forming a copper diffusion barrier. The method comprises sequentially exposing a substrate to a tantalum precursor and a nitrogen reactant to deposit a tantalum nitride film on the substrate in a process chamber. The tantalum nitride film has a thickness of less than or equal to about 20 Å. The substrate is transferred to a PVD process chamber. The tantalum nitride film is biased with an RF power at a second RF power frequency. The tantalum nitride film is etched with at least one gas. The tantalum nitride film is simultaneously doped by sputtering a first and a second source of cobalt onto the tantalum nitride film to form a cobalt-doped tantalum nitride film. The first source of cobalt is supplied with RF power or DC power, and the second source of cobalt is supplied with RF power at a first RF power frequency and with DC power. A cobalt layer is deposited on the cobalt-doped tantalum nitride film by chemical vapor deposition. The cobalt layer comprises bulk cobalt. The cobalt-doped tantalum nitride film and the cobalt layer having a combined thickness of less than or equal to about 45 Å. A copper film is deposited on the cobalt layer. The cobalt layer and the cobalt-doped tantalum nitride film effective to prevent diffusion of copper from the copper film into the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a cross sectional view of a PVD process chamber in accordance with some embodiments of the present disclosure;

FIG. 2 depicts a representational view of an interior volume of the PVD process chamber of FIG. 1, in accordance with some embodiments of the present disclosure;

FIG. 3 depicts a flow diagram of a method of processing a substrate in accordance with some embodiments of the present disclosure; and

FIG. 4 depicts a cluster tool suitable to perform methods for processing a substrate in accordance with some embodiments of the present disclosure.

### DETAILED DESCRIPTION

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

For substrate devices of 7 nm node and smaller, PVD barrier films and copper (Cu) interconnects become more challenging in RC (resistance/capacitance) reduction (interconnect time delay). A thinner barrier layer is required in order to reduce the resistance (R). One also needs to consider improving reflow or electro copper plating (ECP) performance by tuning the barrier process. A continuous barrier is required for an effective Cu barrier. Bevel damage, overhang, via resistance and conformality issues, when combined together, are very challenging to overcome for a PVD process. Using ALD processes typically yields good conformal coverage. However, ALD films may have lower density (due to being metal poor) and higher resistivities. So ALD films (as deposited) are often not effective barriers, and ALD films may also causes higher via resistance (due to the uniform film deposition filling the bottom of the via). Plasma Enhanced ALD (PEALD) processes can improve film density but often damage low k materials (e.g., time dependent dielectric breakdown (TDDB)).

Embodiments of the disclosure provide methods of forming barrier layers and/or liners which advantageously have smaller thicknesses to provide more room for gap fill comprising copper, cobalt, or other metals (e.g., Mo, W, Ir, Ru) in features. This increased volume of gap fill lowers resistivity and RC delay. Additionally, embodiments of the disclosure provide methods of forming barrier layers and/or liners which advantageously prevent diffusion of copper into the substrate, or promote selective deposition of other metals, or improve adhesion of other metals.

Further, embodiments of this disclosure dope the barrier with cobalt and deposit PVD cobalt. This PVD cobalt allows for continuous CVD coverage, which advantageously enhances liner performance. High purity PVD cobalt will facilitate conformal CVD growth and improve copper reflow directly, without CVD cobalt deposition.

The techniques described herein provide solutions to treat films (e.g., ALD films like TaN) with a PVD approach that improves these films for barrier applications (e.g., Cu barrier applications) for 7 nm and below structures. The approach can also be used to enhance or treat (e.g., increase density) other films (i.e. ALD or CVD) for other applications. Typical film stacks that can be processed can include film stacks with, for example, cobalt (Co) and ruthenium (Ru) such as, for example, TaN/Co, TaN/Co/Cu, TaN/Ta/Ru/Cu, or TaN/Ru/Cu and the like. Generally, some embodiments provide film stacks comprising a doped film, a cobalt or ruthenium layer and an optional copper film.

The methods disclosed are applicable to materials and films other than TaN such as other nitrides (e.g., niobium, titanium) as well as films comprising other non-metallic elements (e.g., fluorides, chlorides, carbides). However, for the sake of simplicity, many embodiments described will use TaN as an example

ALD processes can be combined with PVD processes to produce a high quality barrier film. The initial barrier film is deposited on a substrate using ALD processes and then moved to a PVD chamber to treat the barrier film to increase the barrier film's density and purity, thus decreasing the barrier film's resistivity. The processes can be performed with or without a vacuum break between processes.

In general, a film (e.g., TaN) on a substrate is placed in a PVD chamber having a dual frequency (a first and second frequency) which can be used for selective removal of non-metallic elements (e.g., nitrogen) from the film and densifying the film to achieve a PVD-like film for barrier applications. The PVD chamber has dual material sources (a target and a coil) (first and second sources) that can also provide a cobalt source for doping the film and depositing a nucleation layer for later bulk deposition.

In some embodiments, the process includes the deposition of the initial film as well as the treatment thereof. For these embodiments, the process can be carried out in an integrated processing system (i.e., cluster tool) or using single standalone chambers. When an integrated processing system is used, the film is deposited on the substrate and then the substrate is transferred to the PVD chamber for treatment without having a vacuum break. The absence of a vacuum break reduces the overall processing time.

However, the process may also be completed using standalone chambers. In these embodiments, the film is deposited on the substrate in one chamber, and later processed in a separate PVD chamber. In some embodiments, the substrate encounters a vacuum break, and is degassed and pre-cleaned before insertion into the PVD chamber for treatment. In other embodiments, the substrate, after the film is deposited, is stored under an inert gas and transferred to the PVD chamber for processing without a vacuum break.

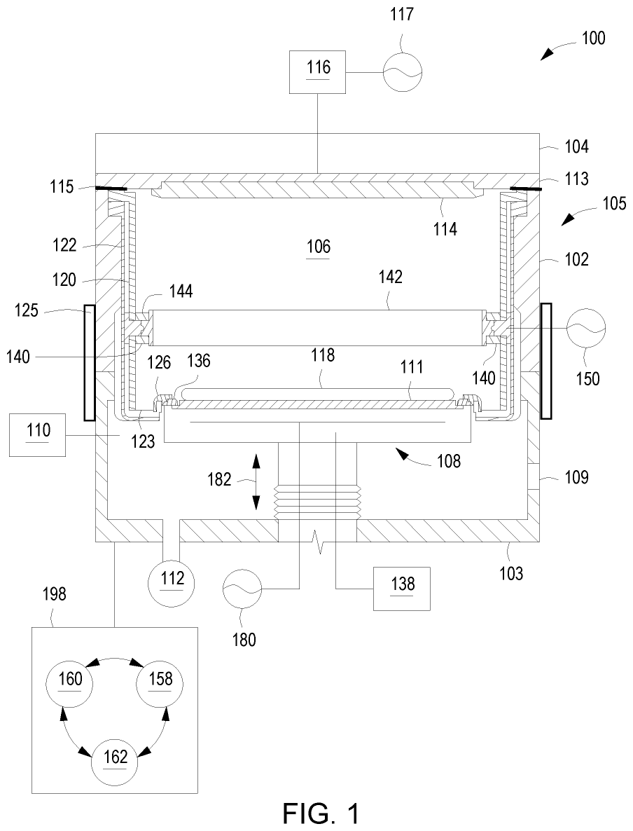

FIG. 1 depicts a schematic, cross-sectional view of an illustrative processing chamber 100 (e.g., a PVD chamber) in accordance with some embodiments of the present disclosure. Examples of suitable PVD chambers include the ENCORE® II and ENCORE® III as well as other PVD processing chambers, commercially available from Applied Materials, Inc., Santa Clara, of Calif. However, the methods disclosed may also be used in processing chambers available from other manufacturers. In one embodiment, the process chamber 100 is capable of depositing, for example metals, metal nitrides, metal fluorides, metal carbides, and the like, on a substrate 118.

The process chamber 100 has a chamber body 105 that includes sidewalls 102, a bottom 103, and a lid assembly 104 all of which enclose an interior volume 106. A substrate support 108 is disposed in a lower portion of the interior volume 106 of the process chamber 100 opposite a target 114. A substrate transfer port 109 is formed in the sidewalls 102 for transferring substrates into and out of the interior volume 106.

A gas source 110 is coupled to the process chamber 100 to supply process gases into the interior volume 106. In one embodiment, process gases may include inert gases, non-reactive gases, and reactive gases, etc. Examples of process gases that may be provided by the gas source 110 include, but not limited to, argon gas (Ar), helium (He), neon gas (Ne), nitrogen gas (N₂), oxygen gas (O₂), hydrogen gas (H₂), and H₂O among others.

A pump 112 is coupled to the process chamber 100 in communication with the interior volume 106 to control the pressure of the interior volume 106. In one embodiment, the pressure of the process chamber 100 may be maintained at greater than zero pressure to about 10 mTorr or less. In another embodiment, the pressure within the process chamber 100 may be maintained at about 3 mTorr.

A backing plate 113 may support the target 114 in an upper portion of the interior volume 106. The backing plate 113 may be electrically isolated from the sidewalls 102 by an isolator 115. The target 114 generally provides a source of material which will be deposited on the substrate 118. The target 114 may be fabricated from a material containing titanium (Ti) metal, tantalum metal (Ta), niobium (Nb) metal, tungsten (W) metal, cobalt (Co), nickel (Ni), copper (Cu), aluminum (Al), manganese (Mn), alloys thereof, combinations thereof, or the like. In an exemplary embodiment depicted herein, the target 114 may be fabricated with cobalt metal (Co).

The target 114 may be coupled to a source assembly 116 comprising a power supply 117 for the target 114. In some embodiments, the power supply 117 may be an RF generator. In some embodiments, the power supply 117 may alternatively be a DC source power supply. In some embodiments, the power supply 117 may include both DC and RF power sources.

An additional RF power source 180 may also be coupled to the process chamber 100 through the substrate support 108 to provide a bias power between the target 114 and the substrate support 108. In one embodiment, the RF power source 180 may provide power to the substrate support 108 to bias the substrate 118 at a frequency between about 1 MHz and about 100 MHz, such as about 13.56 MHz.

The substrate support 108 may be moveable between a raised position and a lowered position, as shown by arrow 182. In the lowered position, a support surface 111 of the substrate support 108 may be aligned with or just below the substrate transfer port 109 to facilitate entry and removal of the substrate 118 to and from the process chamber 100. The support surface 111 may have an edge deposition ring 136 sized to receive the substrate 118 thereon while protecting the substrate support 108 from plasma and deposited material. The substrate support 108 may be moved to the raised position closer to the target 114 for processing the substrate 118 in the process chamber 100. A cover ring 126 may engage the edge deposition ring 136 when the substrate support 108 is in the raised position. The cover ring 126 may prevent deposition material from bridging between the substrate 118 and the substrate support 108. When the substrate support 108 is in the lowered position, the cover ring 126 is suspended above the substrate support 108 and substrate 118 positioned thereon to allow for substrate transfer.

During substrate transfer to/from the process chamber 100, a robot blade (not shown) having the substrate 118 thereon is extended through the substrate transfer port 109. Lift pins (not shown) extend through the support surface 111 of the substrate support 108 to lift the substrate 118 from the support surface 111 of the substrate support 108, thus allowing space for the robot blade to pass between the substrate 118 and substrate support 108. The robot may then carry the substrate 118 into or out of the process chamber 100 through the substrate transfer port 109. Raising and lowering of the substrate support 108 and/or the lift pins may be controlled by a controller 198.

During sputter deposition, the temperature of the substrate 118 may be controlled by utilizing a thermal controller 138 disposed in the substrate support 108. The substrate 118 may be optionally heated to a desired temperature for processing. In some embodiments, the optional heating can be used to bring the substrate and/or film temperature to a temperature of about 200 to about 400 degrees Celsius. In other embodiments, the substrate may be processed at room temperature (about 15 degrees Celsius to about 30 degrees Celsius). In other embodiments the temperature is in a range of about 15 degrees to about 400 degrees Celsius. After processing, the substrate 118 may be rapidly cooled utilizing the thermal controller 138 disposed in the substrate support 108. The thermal controller 138 controls the temperature of the substrate 118, and may be utilized to change the temperature of the substrate 118 from a first temperature to a second temperature in a matter of seconds to about a minute.

An inner shield 120 may be positioned in the interior volume 106 between the target 114 and the substrate support 108. The inner shield 120 may be formed of aluminum or stainless steel among other materials. In one embodiment, the inner shield 120 is formed from stainless steel. An outer shield 122 may be formed between the inner shield 120 and the sidewall 102. The outer shield 122 may be formed from aluminum or stainless steel among other materials. The outer shield 122 may extend past the inner shield 120 and is configured to support the cover ring 126 when the substrate support 108 is in the lowered position.

In one embodiment, the inner shield 120 includes a radial flange 123 that includes an inner diameter that is greater than an outer diameter of the inner shield 120. The radial flange 123 extends from the inner shield 120 at an angle greater than about ninety degrees (90°) relative to the inside diameter surface of the inner shield 120. The radial flange 123 may be a circular ridge extending from the surface of the inner shield 120 and is generally adapted to mate with a recess formed in the cover ring 126 disposed on the substrate support 108. The recessed may be a circular groove formed in the cover ring 126 which centers the cover ring 126 with respect to the longitudinal axis of the substrate support 108.

In some embodiments, the process chamber 100 may include an inductive coil 142. The inductive coil 142 of the process chamber 100 may having one turn or more than one turn. The inductive coil 142 may be just inside the inner shield 120 and positioned above the substrate support 108. The inductive coil 142 may be positioned nearer to the substrate support 108 than the target 114. The inductive coil 142 may be formed from a material similar or equal in composition to the target 114, such as, for example, cobalt, to act as a secondary sputtering target. The inductive coil 142 is supported from the inner shield 120 by a plurality of coil spacers 140. The coil spacers 140 may electrically isolated the inductive coil 142 from the inner shield 120 and other chamber components and to protect from being sputtered on to avoid shorting or creating an unwanted plasma excitation source.

The inductive coil 142 may be coupled to a power source 150. The power source 150 may have electrical leads which penetrate the sidewall 102 of the process chamber 100, the outer shield 122, the inner shield 120 and the coil spacers 140. The electrical leads connect to an electrical hub 144 on the inductive coil 142 for providing power to the inductive coil 142. The electrical hub 144 may have a plurality of insulated electrical connections for providing power to the inductive coil 142. Additionally, the electrical hubs 144 may be configured to interface with the coil spacers 140 and support the inductive coil 142. The power source 150, in one embodiment, applies current to the inductive coil 142 to induce an RF field within the process chamber 100 and couple power to the plasma for increasing the plasma density, i.e., concentration of reactive ions. In some embodiments, the inductive coil 142 is operated at an RF power frequency less than the RF power frequency of the RF power source 180. In one embodiment, the RF power frequency supplied to the inductive coil 142 is about 2 MHz. In other embodiments the RF power frequency may operate in a range of about 1.8 MHz to about 2.2 MHz. In other embodiments, the RF power frequency may range from about 0.1 MHz to 99 MHz. In some embodiments, the inductive coil 142 is made of a material, such as a metal material, that can be sputtered onto a substrate. The power source 150 may then also apply DC power to the inductive coil 142 to enable sputtering of the inductive coil 142 while coupling RF power to the plasma.

A controller 198 is coupled to the process chamber 100. The controller 198 includes a central processing unit (CPU) 160, a memory 158, and support circuits 162. The controller 198 is utilized to control the process sequence, regulating the gas flows from the gas source 110 into the process chamber 100 and controlling ion bombardment of the target 114 and the inductive coil 142. In one embodiment, the controller 198 adjusts a first RF power level of a first power supply (e.g., RF power source 180), a second RF power level of a second power supply (e.g., power source 150), a first DC power level of the second power supply (e.g., power source 150), and a second DC power level of a third power supply (e.g., power supply 117) while sputtering the target and/or inductive coil and while regulating a flow of an etching gas into the interior volume 106 of the process chamber 100.

The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU 160 into a specific purpose computer (controller) 198 that controls the process chamber 100 such that processes are performed in accordance with the present disclosure. The software routines may also be stored and/or executed by a second controller (not shown) that is located remotely from the process chamber 100.

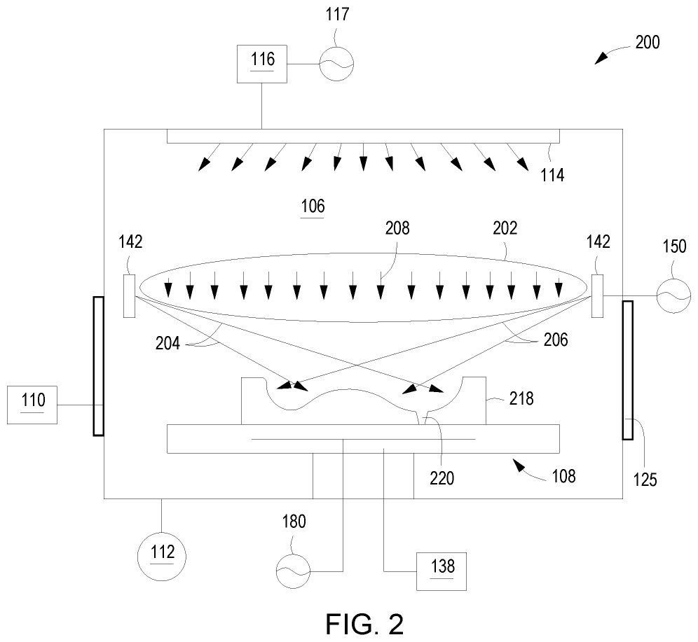

FIG. 2 is a representational view 200 of the interior volume 106 of the process chamber 100 during processing of a substrate 218. In FIG. 2, the features of the substrate 218 have been enlarged so that the features, including sidewalls, bevels and slopes, can be easily seen for illustrative purposes. One skilled in the art will understand that the features of the substrate 218 shown in FIG. 2 are not shown to scale. When processing the substrate 218, the PVD process chamber uses power supply 117 and power source 150 for sputtering a metal such as, for example, cobalt. In some embodiments, the power supply 117 operates to produce DC power to sputter the target 114 while the power source 150 operates as a DC source to sputter the inductive coil 142 and operates as an RF power source at a frequency less than the operating RF frequency of the RF power source 180 to increase the plasma density in the interior volume 106. In some embodiments the power source 150 operates at an RF power frequency of about 0.1 MHz to 99 MHz. In other embodiments the power source 150 operates at an RF power frequency of about 1.8 MHz to about 2.2 MHz.

In some embodiments, the target 114 and the inductive coil 142 are composed of the same material such as, for example, cobalt. The dual sources aid in providing a stable plasma and enough energy to selectively etch non-metallic elements (e.g., nitrogen from a nitride film) while keeping a metal film intact or at least minimally etched. The RF power source 180 operates at an RF power frequency greater than the operating RF power frequency of the power source 150 to bias the substrate 218. In some embodiments the RF power source 180 operates at an RF power frequency of about 1 MHz to about 100 MHz. In other embodiments, the RF power source operates at an RF power frequency of about 13.56 MHz.

In some embodiments, the gas source 110 supplies a gas 208 into the interior volume 106. In some embodiments, the gas 208 comprises a noble gas such as, for example, argon (Ar), helium (He), xenon (Xe), neon (Ne), or krypton (Kr). In some embodiments, the gas 208 comprises a reactive gas, such as, for example, a nitrogen-based gas (N₂ or NH₃) or hydrogen gas (H₂). In some embodiments, the gas 208 can also be a combination of a one or more noble gases and one or more reactive gases. The gas 208 is introduced into plasma 202 formed above the substrate 218. The pump 112 keeps the interior volume 106 at a pressure of less than or equal to about 10 mTorr while the thermal controller 138 keeps the substrate 218 at about 200 to about 400 degrees Celsius or at room temperature (about 15 degrees Celsius to about 30 degrees Celsius), or any temperature there between (e.g., about 15° C. to about 400° C.). The target 114 sputters ions at random angles incident to the substrate 218 and, often, the angles do not provide good coverage on vertical or near vertical (sloping) features on the substrate 218. The inductive coil 142 provides ions sputtered at acute angles 204, 206 to the substrate 218 to provide coverage on sidewall, bevels, and sloping features of structures on the substrate 218. In some embodiments, a magnetic field is used to control ion distribution. The magnetic field, in some embodiments, can be dynamically controlled by an electromagnet 125 to affect where the ions are distributed on the substrate 118.

In some embodiments, the film is provided on a substrate with at least one feature. As used in this regard, a feature may have vertical or near vertical sidewalls and a bottom. In some embodiments, the film is present on the sidewalls and bottom of the substrate feature. In some embodiments, the film is conformal to the substrate feature.

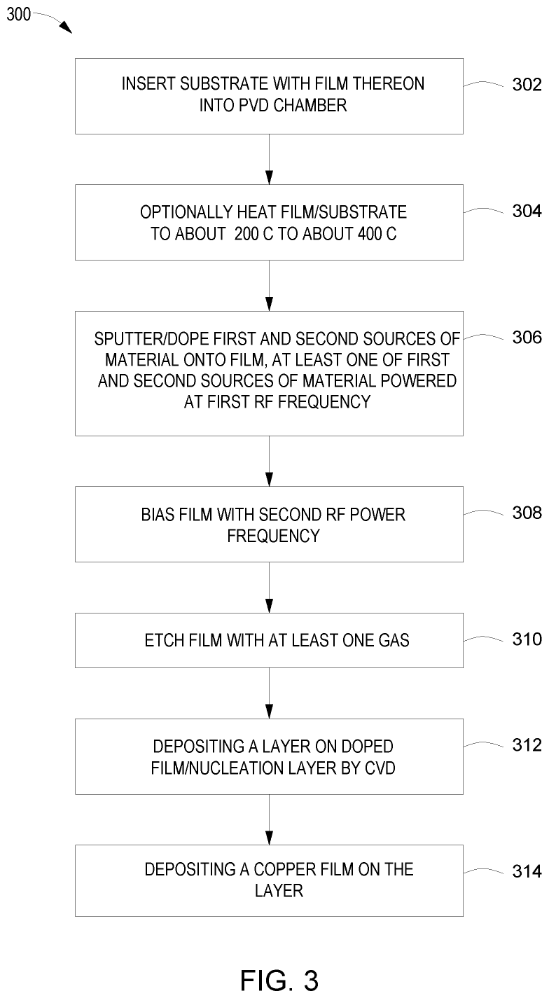

FIG. 3 is a method 300 for processing a film deposited on a substrate according to some embodiments of the present disclosure. The processes are shown in an orderly fashion, but there is no requirement that the processes be performed in an exact sequence or that all processes must be performed. Some processes may come before or after other processes or be performed at the same time. Iterations can occur between processes before performing other processes. References are made to elements shown in both FIGS. 1 and 2. Method 300 starts by inserting a substrate with a film thereon into a PVD chamber as indicated at 302. In some embodiments, the PVD chamber is pressurized to a pressure greater than zero pressure to less than or equal to about 10 mTorr. In some embodiments, the process chamber is maintained at about 3 mTorr.

In some embodiments, the method 300 begins with the film already deposited on the substrate. In some embodiments, the film is deposited on the substrate as part of the method.

The film may be any suitable thickness. In some embodiments, the thickness of each layer or film is minimized. Without being bound by theory, it is believed that smaller barrier and liner layers provide lower resistivity and reduce RC delays. In some embodiments, the film has a thickness of less than or equal to about 20 Å, less than or equal to about 18 Å, less than or equal to about 15 Å, less than or equal to about 14 Å, less than or equal to about 13 Å, less than or equal to about 12 Å, less than or equal to about 11 Å, or less than or equal to about 10 Å.

In some embodiments, the film is deposited on the substrate by an atomic layer deposition (ALD) process. In some embodiments, the ALD process comprises sequentially exposing the substrate to a metal precursor and a reactant. Those skilled in the art will recognize the metal precursors and reactants suitable for producing a film with a predetermined composition. In some embodiments, a TaN film is deposited by exposing a substrate to a tantalum precursor and a nitrogen reactant. In some embodiments, the tantalum precursor comprises pentakis(dimethylamino)tantalum. In some embodiments, the nitrogen reactant comprises one or more of nitrogen gas (N₂), ammonia, nitrous oxide or nitrogen dioxide.

In some embodiments, the film comprises tantalum carbide, tantalum nitride, tantalum fluoride, niobium carbide, niobium nitride, niobium fluoride, titanium carbide, titanium nitride, titanium fluoride, or combinations thereof. In some embodiments, the film comprises more than one metal species (e.g., TiTaN). In some embodiments, the film comprises more than one non-metallic element (e.g., TaCN).

In some embodiments, the film/substrate temperature may be at room temperature during processing. In some embodiments, the film/substrate may be optionally heated to about 200 degrees to about 400 degrees Celsius as indicated at 304. In other embodiments, the film/substrate may be optionally heated from about 15 degrees Celsius to about 400 degrees Celsius. The PVD chamber environment may be maintained at a room temperature or at a medium (e.g., 200° C.) to high (e.g., 400° C.) temperature and very low (e.g., <10 mTorr) pressure environment during the film treatment. In some embodiments, the temperature of the substrate and/or film is maintained at about 325 degrees Celsius. The film on the substrate can be composed of any type of material or combinations of material. For the sake of brevity, the examples of the embodiments use TaN as the film to be treated. In some embodiments, the film is deposited by ALD and before being treated in the PVD chamber has the typical properties associated with ALD, namely that if used as a barrier film, the film is conformal but has low density and high resistivity, making the ALD film a poor barrier film.

Power is applied to a target, such as the target 114, a coil, such as the inductive coil 142, and a biasing component, such as RF power source 180, to generate sputtering/doping and plasma as indicated at 306 and 308. The target 114 is generally a metallic material (e.g., cobalt) and is sputtered using DC power from a power supply such as power supply 117. RF power can be used if the target 114 is a metal oxide material. In one embodiment, the coil, such as the inductive coil 142, is operated as a DC power source and as an RF power source with a frequency of about 0.1 MHz to about 99 MHz (e.g., about 1.8 MHz to about 2.2 MHz in some embodiments) while the biasing component, such as RF power source 180, is operated at a frequency greater than that of the frequency used for the inductive coil 142 (e.g., a frequency of about 13.56 MHz in some embodiments). DC power may also be applied to the inductive coil 142 together with RF power. As illustrated in FIG. 2, the target 114 is sputtered which releases randomly directed ions that generally impact the substrate 218 at generally perpendicular incidence angles to dope the film with material from the target 114 (e.g., cobalt). The inductive coil 142 is sputtered as well and the ions from the inductive coil 142 are directed at acute angles 204, 206 to the surface of the substrate 218. The sputtering from the inductive coil 142 dopes the sidewalls, bevels and slopes of the substrate 218 with material from the inductive coil 142 (e.g., cobalt). The dual sources allow for selective doping of the film (i.e., controlled doping levels on different substrate surfaces).

The film is doped and etched to increase density and remove non-metallic elements from the film as indicated at 310. In some embodiments, the doping and etching processes are performed simultaneously. As used in this regard, processes which are performed simultaneously are conducted, at least in part, at the same time. In some embodiments, the doping and etching processes are performed sequentially. As used in this regard, processes which are performed sequentially are performed in sequence. For example, the doping may be performed first, the doping process stopped, and then the etching process performed second. Alternatively, the etching process may be performed sequentially before the doping process.

The PVD chamber environment, such as the interior volume 106, is filled with at least one gas, such as, for example, argon or nitrogen or hydrogen or other noble gases and/or reactive gases, and at a pressure greater than zero pressure and less than or equal to about 10 mTorr. The gas, such as gas 208 of FIG. 2, is used to provide an etch of the substrate, such as substrate 218, to release non-metallic elements from the film (e.g., nitrogen from a nitride film). Without being bound by theory, it is believed that if the pressure is not kept very low, some materials, such as tantalum, have a high affinity for oxygen and higher pressures may produce nitrogen oxide, making the nitrogen removal inefficient.

The gas 208 provides a low energy (0 v to −300 v) etching of the surface of the substrate 218. The low energy etching allows for selective removal of non-metallic elements from the film. The low energy etching is selective because the etching removes non-metallic elements with negligible or no removal of tantalum or other metallic materials. The etching typically has the greatest effect on surfaces that are perpendicular to the substrate support such as the bottom of a via 220 that is to be used as a connection point. Because the etching rate is higher at the bottom of the via 220, the resistivity of the via 220 is greatly decreased. The sputtering of the inductive coil 142 aids in protecting those features of the substrate 218 that would be etched too excessively, maintaining a material thickness in those areas. The dual sources (first and second sources of a material)—target 114 and inductive coil 142—provide both bevel protection and off angle (acute angle) treatment for sidewalls. In some embodiments, the treatment duration is up to about 10 seconds. In some embodiments, only the inductive coil 142 with a low voltage (0 v to −1000 v) is used as a source during some portions of the treatment (i.e. the target 114 is not sputtered) and an etch is performed. The low voltage of the inductive coil 142 significantly reduces the sputtering of the inductive coil 142, leaving predominately only the gas etching.

A PVD flash is generally performed after the gas etch to protect any bevel features of a device on a substrate. The PVD flash deposits a thin layer of PVD film (e.g., about 3 to about 20 Angstroms) to improve surface morphology.

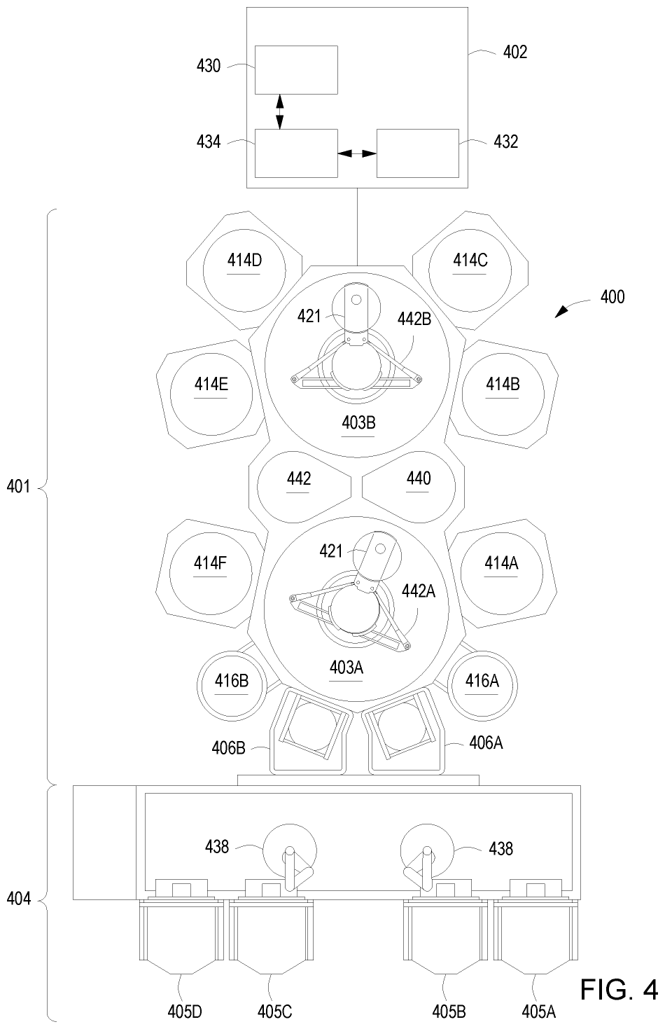

In one embodiment, the RF power used for the inductive coil 142 is about 100 watts to about 5000 watts with the bias power at about 100 watts to about 1000 watts or less. The gas flow rate provided by the gas source 110 is about 100 sccm (standard cubic centimeters per minute) or less. The interior volume 106 pressure is maintained at about 3 mTorr. The substrate temperature is maintained by the thermal controller 138 at about 325 degrees Celsius. The treatment is about 2 seconds to about 3 seconds in duration. Without being bound by theory, it is believed that the shorter duration allows for a higher processing volume (e.g., throughput), especially when using an integrated system or cluster tool (see below, FIG. 4).

The film, after being treated in the PVD chamber, has the typical properties associated with PVD processes but with the conformal properties of an ALD film. The dynamic treatment process creates a long lasting, high quality barrier film with high density and low resistivity.

The method of treating the film in the PVD chamber dopes the film with first and second sources of materials, the target and coil, respectively, to form a doped film. In some embodiments, the film is doped with cobalt from a first source of cobalt and a second source of cobalt.

In some embodiments, the method 300 of treating the film in the PVD chamber deposits a cobalt nucleation layer on the doped film. A skilled artisan will understand that a nucleation layer need not be continuous on the surface of the doped film, but provides nucleation sites to improve the growth and adhesion of a deposited layer. The cobalt nucleation layer may have an average thickness in a range of 5 Å to 40 Å. In some embodiments, the average thickness of the cobalt nucleation layer is greater than or equal to about 5 Å and less than or equal to about 40 Å, less than or equal to about 35 Å, less than or equal to about 30 Å, less than or equal to about 25 Å, less than or equal to about 20 Å, less than or equal to about 15 Å, or less than or equal to about 10 Å. In some embodiments, the cobalt nucleation layer is present with an average thickness of less than or equal to 5 Å.

In some embodiments, the method continues by optionally depositing a layer by chemical vapor deposition (CVD) on the cobalt nucleation layer as indicated at 312. In some embodiments, the deposited layer is a bulk metallic layer. In some embodiments, the bulk metallic layer comprises cobalt, ruthenium, tungsten, molybdenum, or iridium. In some embodiments, the layer comprises or consists essentially of cobalt (Co). In some embodiments, the layer comprises or consists essentially of ruthenium (Ru). As used in this regard, a layer which consists essentially of a stated material comprises greater the 95%, 98%, 99% or 99.5% of the stated material.

In some embodiments, the layer may have a thickness in a range of 10 Å to 15 Å. In some embodiments, the thickness of the layer is less than or equal to about 30 Å, less than or equal to about 25 Å, less than or equal to about 20 Å, less than or equal to about 15 Å, or less than or equal to about 10 Å.

In some embodiments where the cobalt nucleation layer is not present, the doped film and the layer are considered a film stack with a thickness less than or equal to about 45 Å. In some embodiments where the cobalt nucleation layer is present, the doped film, the cobalt nucleation layer and the layer are considered a film stack with a thickness less than or equal to about 45 Å. In some embodiments, the film stack, regardless of the presence or absence of a cobalt nucleation layer, has a thickness less than or equal to about 45 Å, less than or equal to about 40 Å, less than or equal to about 35 Å, less than or equal to about 30 Å, or less than or equal to about 25 Å.

In some embodiments, the method continues by optionally depositing a copper film on the layer as indicated at 314. Those skilled in the art will recognize suitable processes for depositing a copper film, including but not limited to CVD, ALD and PVD processes. In some embodiments, the layer is effective to prevent diffusion of copper from the copper film into the substrate. In some embodiments, the layer promotes adhesion for other metal deposition or facilitates selective metal deposition.

The methods described herein may be performed in individual process chambers that may be provided in a standalone configuration or as part of a cluster tool, for example, an integrated tool 400 (i.e., cluster tool) described below with respect to FIG. 4. The advantage of using an integrated tool 400 is that there is no vacuum break and no requirement to degas and pre-clean a substrate before treatment in a PVD chamber. Examples of the integrated tool 400 include the CENTURA® and ENDURA® integrated tools, available from Applied Materials, Inc., of Santa Clara, Calif. However, the methods described herein may be practiced using other cluster tools having suitable process chambers, or in other suitable process chambers. For example, in some embodiments the inventive methods discussed above may advantageously be performed in an integrated tool such that there are limited or no vacuum breaks between processes. For example, reduced vacuum breaks may limit or prevent contamination of the substrate.

The integrated tool 400 includes a vacuum-tight processing platform 401, a factory interface 404, and a system controller 402. The processing platform 401 comprises multiple processing chambers, such as 414A, 414B, 414C, 414D, 414E, and 414F operatively coupled to a vacuum substrate transfer chamber (transfer chambers 403A, 403B). The factory interface 404 is operatively coupled to the transfer chamber 403A by one or more load lock chambers (two load lock chambers, such as 406A and 406B shown in FIG. 4).

In some embodiments, the factory interface 404 comprises at least one docking station 407, at least one factory interface robot 438 to facilitate the transfer of the semiconductor substrates. The docking station 407 is configured to accept one or more front opening unified pod (FOUP). Four FOUPS, such as 405A, 405B, 405C, and 405D are shown in the embodiment of FIG. 4. The factory interface robot 438 is configured to transfer the substrates from the factory interface 404 to the processing platform 401 through the load lock chambers, such as 406A and 406B. Each of the load lock chambers 406A and 406B have a first port coupled to the factory interface 404 and a second port coupled to the transfer chamber 403A. The load lock chamber 406A and 406B are coupled to a pressure control system (not shown) which pumps down and vents the load lock chambers 406A and 406B to facilitate passing the substrates between the vacuum environment of the transfer chamber 403A and the substantially ambient (e.g., atmospheric) environment of the factory interface 404. The transfer chambers 403A, 403B have vacuum robots 442A, 442B disposed in the respective transfer chambers 403A, 403B. The vacuum robot 442A is capable of transferring substrates 421 between the load lock chamber 406A, 406B, the processing chambers 414A and 414F and a cooldown station 440 or a pre-clean station 442. The vacuum robot 442B is capable of transferring substrates 421 between the cooldown station 440 or pre-clean station 442 and the processing chambers 414B, 414C, 414D, and 414E.

In some embodiments, the processing chambers 414A, 414B, 414C, 414D, 414E, and 414F are coupled to the transfer chambers 403A, 403B. The processing chambers 414A, 414B, 414C, 414D, 414E, and 414F comprise at least an atomic layer deposition (ALD) process chamber and a physical vapor deposition (PVD) process chamber. Additional chambers may also be provided such as CVD chambers, annealing chambers, additional ALD chambers, additional PVD chambers, or the like. ALD and PVD chambers may include any chambers suitable to perform all or portions of the methods described herein, as discussed above.

In some embodiments, one or more optional service chambers (shown as 416A and 4168) may be coupled to the transfer chamber 403A. The service chambers 416A and 416B may be configured to perform other substrate processes, such as degassing, orientation, substrate metrology, cool down and the like.

The system controller 402 controls the operation of the tool 400 using a direct control of the process chambers 414A, 414B, 414C, 414D, 414E, and 414F or alternatively, by controlling the computers (or controllers) associated with the process chambers 414A, 414B, 414C, 414D, 414E, and 414F and the tool 400. In operation, the system controller 402 enables data collection and feedback from the respective chambers and systems to optimize performance of the tool 400. The system controller 402 generally includes a Central Processing Unit (CPU) 430, a memory 434, and a support circuit 432. The CPU 430 may be any form of a general purpose computer processor that can be used in an industrial setting. The support circuit 432 is conventionally coupled to the CPU 430 and may comprise a cache, clock circuits, input/output subsystems, power supplies, and the like. Software routines, such as a method as described above may be stored in the memory 434 and, when executed by the CPU 430, transform the CPU 430 into a specific purpose computer (system controller 402). The software routines may also be stored and/or executed by a second controller (not shown) that is located remotely from the tool 400.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of doping a film, the method comprising:
providing a substrate with a film deposited thereon;
biasing the substrate with an RF power at a first RF power frequency to provide a biased substrate;
etching the film on the biased substrate with at least one gas; and
sputtering first and second sources of cobalt onto the film on the biased substrate to form a doped film, the first source of cobalt supplied with RF power or DC power and the second source of cobalt supplied with RF power at a second RF power frequency and with DC power.

2. The method of claim 1, wherein the film comprises tantalum carbide, tantalum nitride, tantalum fluoride, niobium carbide, niobium nitride, niobium fluoride, titanium carbide, titanium nitride, titanium fluoride, or combinations thereof.

3. The method of claim 1, wherein the at least one gas comprises a noble gas, a nitrogen-based gas or hydrogen gas.

4. The method of claim 1, wherein etching the film and sputtering the first and second sources of cobalt are sequential.

5. The method of claim 1, wherein etching the film and sputtering the first and second sources of cobalt are simultaneous.

6. The method of claim 1, wherein the second source of cobalt is sputtered at an acute angle to the substrate.

7. The method of claim 1, wherein the film is less than or equal to about 20 Å.

8. The method of claim 1, wherein sputtering the first and second sources of cobalt deposits a cobalt nucleation layer on the doped film.

9. The method of claim 8, wherein the cobalt nucleation layer has an average thickness in a range of about 5 Å to about 40 Å.

10. The method of claim 8, further comprising depositing a layer by chemical vapor deposition on the cobalt nucleation layer.

11. The method of claim 10, wherein the layer consists essentially of cobalt or ruthenium.

12. The method of claim 10, wherein the layer has a thickness of less than or equal to about 30 Å.

13. The method of claim 10, wherein the doped film, the cobalt nucleation layer and the layer have a combined thickness in a range of about 15 Å to about 45 Å.

14. The method of claim 1, further comprising:
sputtering with only the second source of cobalt onto the biased substrate; and
etching the film with at least one gas while sputtering only the second source of cobalt.

15. The method of claim 1, wherein the doped film is present in a film stack, the film stack comprising the doped film, a cobalt or ruthenium film and an optional copper film.

16. A method of forming a doped film, the method comprising:
depositing a film on a substrate in a process chamber;
transferring the substrate to a physical vapor deposition process chamber;
biasing the film with an RF power at a second RF power frequency;
etching the film with at least one gas; and
simultaneously doping the film by sputtering a first and a second source of cobalt onto the film to form a doped film, the first source of cobalt supplied with RF power or DC power and the second source of cobalt supplied with RF power at a first RF power frequency and with DC power.

17. The method of claim 16, wherein the film is deposited by sequentially exposing the substrate to a metal precursor and a reactant.

18. The method of claim 16, wherein the doped film provides a cobalt nucleation layer, and the method further comprises depositing a layer comprising bulk cobalt, ruthenium, tungsten, molybdenum, or iridium by chemical vapor deposition.

19. The method of claim 18, wherein the doped film and the layer have a combined thickness of less than or equal to about 45 Å.

20. A method of forming a copper diffusion barrier, the method comprising:
sequentially exposing a substrate to a tantalum precursor and a nitrogen reactant to deposit a tantalum nitride film on the substrate in a process chamber, the tantalum nitride film having a thickness of less than or equal to about 20 Å;
transferring the substrate to a PVD process chamber;
biasing the tantalum nitride film with an RF power at a second RF power frequency;
etching the tantalum nitride film with at least one gas;
simultaneously doping the tantalum nitride film by sputtering a first and a second source of cobalt onto the tantalum nitride film to form a cobalt-doped tantalum nitride film, the first source of cobalt supplied with RF power or DC power and the second source of cobalt supplied with RF power at a first RF power frequency and with DC power;
depositing a cobalt layer on the cobalt-doped tantalum nitride film by chemical vapor deposition, the cobalt layer comprising bulk cobalt, the cobalt-doped tantalum nitride film and the cobalt layer having a combined thickness of less than or equal to about 25 Å; and
depositing a copper film on the cobalt layer, the cobalt layer and the cobalt-doped tantalum nitride film effective to prevent diffusion of copper from the copper film into the substrate.
